(19) United States
(12) Patent Application Publication
(10) Pub. No.: US 2024/0249059 A1
(43) Pub. Date: Jul. 25, 2024

(54) METHOD FOR REMOVING DEAD SPACE WITH REGARD TO SEMICONDUCTOR DESIGN

(71) Applicant: MakinaRocks Co., Ltd., Seoul (KR)

(72) Inventors: Wooshik Myung, Seoul (KR); Jiyoon Lim, Seoul (KR); Seungju Kim, Seoul (KR); Wonjun Yoo, Seoul (KR)

(73) Assignee: MakinaRocks Co., Ltd., Seoul (KR)

(21) Appl. No.: 18/417,756

(22) Filed: Jan. 19, 2024

(30) Foreign Application Priority Data
Jan. 25, 2023 (KR) 10-2023-0009530

(51) Int. Cl. G06F 30/392

(52) U.S. Cl. CPC G06F 30/392

(57) ABSTRACT

Disclosed is a method for placing a semiconductor cell, which is performed by a computing device, and the method may include: determining a placement location of a macro cell in a design area using a reinforcement learning model; determining a candidate direction for shifting the placement location of the macro cell determined by the reinforcement learning model; and shifting the placement location of the macro cell based on the determined candidate direction, and the determined candidate direction may include a direction facing an outside of the design area.

### CROSS-REFERENCE TO RELATED APPLICATIONS

This application claims priority to and the benefit of Korean Patent Application No. 10-2023-0009530 filed in the Korean Intellectual Property Office on Jan. 25, 2023, the entire contents of which are incorporated herein by reference.

### TECHNICAL FIELD

The present disclosure relates to a semiconductor design method, and more particularly, to a method for optimizing a design of a semiconductor by removing a dead space which may be generated in a design area of the semiconductor.

### BACKGROUND ART

Currently, in designing semiconductors, there is a trend in which some tasks are being automated in manual design that should depend on the overall intuition and experience of engineers. Nevertheless, there are so many things to consider in the optimal semiconductor design, so it is realistically constrained to achieve optimized design at once. At this time, as a factor that interferes with optimization, there may be an area (in other words, dead space) which occupies an empty space in the design area but where no cell can be placed. In general, the more dead space, the lower the density of the semiconductor, and the lower the density, the higher the process price and the lower the power efficiency. Therefore, in the art, a demand for solutions that will further optimize a result during the semiconductor design process or after completion of the design is increasing.

On the other hand, the present disclosure has been derived at least based on the technical background described above, but the technical problem or object of the present disclosure is not limited to solving the problems or disadvantages described above. That is, the present disclosure may cover various technical issues related to the content to be described below, in addition to the technical issues discussed above.

On the other hand, US 2007/0157146 A1 (Jul. 5, 2007) discloses a design method of a semiconductor.

### SUMMARY OF THE INVENTION

The present disclosure is contrived in response to the above-mentioned background art, and has been made in an effort to optimize a process of designing a semiconductor or a space of the designed semiconductor. For example, the present disclosure has been made in an effort to remove a dead space which may be generated in the design process of the semiconductor.

Meanwhile, a technical object to be achieved by the present disclosure is not limited to the above-mentioned technical object, and various technical objects can be included within the scope which is apparent to those skilled in the art from contents to be described below.

An exemplary embodiment of the present disclosure provides a method for placing a semiconductor cell, which is performed by a computing device. The method may include: determining a placement location of a macro cell in a design area using a reinforcement learning model; determining a candidate direction for shifting the placement location of the macro cell determined by the reinforcement learning model; and shifting the placement location of the macro cell based on the determined candidate direction, and the determined candidate direction may include a direction facing an outside of the design area.

As an exemplary embodiment, the direction facing of the outside of the design area may include at least one direction of a direction facing a corner of the design area or a direction facing an edge of the design area.

As an exemplary embodiment, the design area may include a canvas area for placing the semiconductor cell.

As an exemplary embodiment, the direction facing the corner of the design area may include a direction facing a corner closest to the placement location of the macro cell among a plurality of corners of the canvas.

As an exemplary embodiment, the direction facing the corner closest to the placement location of the macro cell may be determined based on identifying a quadrant includes the macro cells among quadrants of the canvas.

As an exemplary embodiment, the direction facing the edge of the design area may be determined based on a bounding box of the macro group includes the macro cells.

As an exemplary embodiment, the direction facing the edge of the design area may include at least one direction of a direction facing an edge closest to the bounding box of the macro group includes the macro cells among edges of the canvas or a direction facing an edge second closest.

As an exemplary embodiment, the determining of the candidate direction for shifting the placement location of the macro cell determined by the reinforcement learning model may include determining a plurality of candidate directions for shifting the placement location of the macro cell, and the shifting of the placement location of the macro cell may include shifting the placement location of the macro cell based on the plurality of determined candidate directions.

As an exemplary embodiment, the plurality of determined candidate directions may include a direction facing one corner among the plurality of corners of the design area, and a direction facing one edge among the plurality of edges of the design area.

As an exemplary embodiment, the plurality of determined candidate directions may include two or more directions facing two or more edges among the plurality of edges of the design area.

As an exemplary embodiment, the plurality of determined candidate directions may include the direction facing one corner among the plurality of corners of the design area, and two or more directions facing two or more edges among the plurality of edges of the design area.

As an exemplary embodiment, the direction facing one corner among the plurality of corners of the design area may be determined by the unit of an individual macro cell.

As an exemplary embodiment, the directions facing two or more edges among the plurality of edges of the design area may be determined by the unit of the macro group including a plurality of macro cells.

As an exemplary embodiment, the placement location of the macro cell determined by the reinforcement learning model may include at least one of the placement location of the macro cell, or the placement location by the unit of the macro group includes the macro cells.

As an exemplary embodiment, the placement location of the macro cell determined by the reinforcement learning model may include a final placement location determined by completion of reinforcement learning by the reinforcement learning model.

As an exemplary embodiment, the placement location of the macro cell determined by the reinforcement learning model may include a placement location determined in the process of the reinforcement learning by the reinforcement learning model.

As an exemplary embodiment, placement location determined in the process of the reinforcement learning by the reinforcement learning model may include a placement location associated with an episode related to calculation of a reward of the reinforcement learning.

As an exemplary embodiment, the reward of the reinforcement learning may be calculated by considering the shift of the placement location of the macro cell based on the determined candidate direction.

Another exemplary embodiment of the present disclosure provides a computing device. The computing for designing a semiconductor may include: at least one processor; and a memory, and the at least one processor may be configured to determine a placement location of a macro cell in a design area using a reinforcement learning model, determine a candidate direction for shifting the placement location of the macro cell determined by the reinforcement learning model, and shift the placement location of the macro cell based on the determined candidate direction, and the determined candidate direction may include a direction facing an outside of the design area.

As an exemplary embodiment related to the device, the at least one processor may be additionally configured to determine a plurality of candidate directions for shifting the placement location of the macro cell, and shift the placement location of the macro cell based on the plurality of determined candidate directions.

As an exemplary embodiment related to the device, the plurality of determined candidate directions may include a direction facing one corner among the plurality of corners of the design area, and a direction facing one edge among the plurality of edges of the design area.

As an exemplary embodiment related to the device, the plurality of determined candidate directions may include two or more directions facing two or more edges among the plurality of edges of the design area. As an exemplary embodiment related to the device, the plurality of determined candidate directions may include the direction facing one corner among the plurality of corners of the design area, and two or more directions facing two or more edges among the plurality of edges of the design area.

As an exemplary embodiment related to the device, the direction facing one corner among the plurality of corners of the design area may be determined by the unit of an individual macro cell.

As an exemplary embodiment related to the device, the directions facing two or more edges among the plurality of edges of the design area may be determined by the unit of the macro group including a plurality of macro cells.

Still another exemplary embodiment of the present disclosure provides a program. The computer program may be stored in a computer-readable storage medium, and when the computer program is executed by at least one processor, the computer program may allow the at least one processor to perform operations of placing a semiconductor cell, and the operations may include: an operation of determining a placement location of a macro cell in a design area using a reinforcement learning model; an operation of determining a candidate direction for shifting the placement location of the macro cell determined by the reinforcement learning model; and an operation of shifting the placement location of the macro cell based on the determined candidate direction, and the determined candidate direction may include a direction facing an outside of the design area.

As an exemplary embodiment related to the program, the direction facing of the outside of the design area may include at least one direction of a direction facing a corner of the design area or a direction facing an edge of the design area.

As an exemplary embodiment related to the program, the design area may include a canvas area for placing the semiconductor cell, and the direction facing the corner of the design area may include a direction facing a corner closest to the placement location of the macro cell among a plurality of corners of the canvas.

As an exemplary embodiment related to the program, the direction facing the corner closest to the placement location of the macro cell may be determined based on identifying a quadrant includes the macro cells among quadrants of the canvas.

As an exemplary embodiment related to the program, the direction facing the edge of the design area may be determined based on a bounding box of the macro group includes the macro cells.

As an exemplary embodiment related to the program, the design area may include a canvas area for placing the semiconductor cell, and the direction facing the edge of the design area may include at least one direction of a direction facing an edge closest to the bounding box of the macro group includes the macro cells among edges of the canvas or a direction facing an edge second closest.

According to an exemplary embodiment of the present disclosure, in designing the semiconductor a semiconductor cell is placed or a placement location of the placed semiconductor cell is shifted to optimize a design of the semiconductor.

For example, according to an exemplary embodiment of the present disclosure, in a canvas in which a macro cell is already placed, placement locations of semiconductor cells are shifted to face an outside of the canvas to optimize the design of the semiconductor.

According to an exemplary embodiment of the present disclosure, when a reinforcement learning model places the semiconductor cell in a design area, the design area is optimized at every placement, which can allow the reinforcement learning model to consider the optimization of the design area in placing the semiconductor cell. For example, a dead space in the design area is removed to improve a power, performance, area (PPA).

Meanwhile, the effects of the present disclosure are not limited to the above-mentioned effects, and various effects can be included within the scope which is apparent to those skilled in the art from contents to be described below.

### BRIEF DESCRIPTION OF THE DRAWINGS

FIG. 1 is a block diagram of a computing device according to an exemplary embodiment of the present disclosure.

FIG. 2 is a conceptual view illustrating a neural network according to an exemplary embodiment of the present disclosure.

FIG. 3 is a schematic view illustrating a basic semiconductor design process.

FIG. 4 is a conceptual view illustrating a reinforcement learning process.

FIG. 5 is an exemplary diagram illustrating placement of a semiconductor cell which needs to be optimized.

FIG. 6 is a block diagram illustrating modules according to an exemplary embodiment of the present disclosure.

FIG. 7 is an exemplary diagram of a method for shifting a location of a macro cell by a first location shift module according to an exemplary embodiment of the present disclosure.

FIG. 8 is an exemplary diagram of a method for shifting a location of a macro group by a second location shift module according to an exemplary embodiment of the present disclosure.

FIG. 9A is a flowchart of a method for optimizing a semiconductor design using a first location shift module according to an exemplary embodiment of the present disclosure.

FIG. 9B is a flowchart of a method for optimizing the semiconductor design using a second location shift module according to an exemplary embodiment of the present disclosure.

FIG. 9C is a flowchart of a method for optimizing the semiconductor design using the first and second location shift modules according to an exemplary embodiment of the present disclosure.

FIG. 10 is a flowchart illustrating a schematic sequence for a method for placing a semiconductor cell according to an exemplary embodiment of the present disclosure.

FIG. 11 is a conceptual view of a computing environment according to an exemplary embodiment of the present disclosure.

### DETAILED DESCRIPTION

Various exemplary embodiments are described with reference to the drawings. In the present specification, various descriptions are presented for understanding the present disclosure. However, it is obvious that the exemplary embodiments may be carried out even without a particular description.

Terms, “component”, “module”, “system”, and the like used in the present specification indicate a computer-related entity, hardware, firmware, software, a combination of software and hardware, or execution of software. For example, a component may be a procedure executed in a processor, a processor, an object, an execution thread, a program, and/or a computer, but is not limited thereto. For example, both an application executed in a computing device and a computing device may be components. One or more components may reside within a processor and/or an execution thread. One component may be localized within one computer. One component may be distributed between two or more computers. Further, the components may be executed by various computer readable media having various data structures stored therein. For example, components may communicate through local and/or remote processing according to a signal (for example, data transmitted to another system through a network, such as the Internet, through data and/or a signal from one component interacting with another component in a local system and a distributed system) having one or more data packets.

Further, a term “or” intends to mean comprehensive “or” not exclusive “or”. That is, unless otherwise specified or when it is unclear in context, “X uses A or B” intends to mean one of the natural comprehensive substitutions. That is, in the case where X uses A; X uses B; or, X uses both A and B, “X uses A or B” may apply to either of these cases. Further, a term “and/or” used in the present specification shall be understood to designate and include all of the possible combinations of one or more items among the listed relevant items.

Further, a term “include” and/or “including” shall be understood as meaning that a corresponding characteristic and/or a constituent element exists. Further, it shall be understood that a term “include” and/or “including” means that the existence or an addition of one or more other characteristics, constituent elements, and/or a group thereof is not excluded. Further, unless otherwise specified or when it is unclear that a single form is indicated in context, the singular shall be construed to generally mean “one or more” in the present specification and the claims.

Further, the term “at least one of A and B” should be interpreted to mean “the case including only A”, “the case including only B”, and “the case where A and B are combined”.

Those skilled in the art shall recognize that the various illustrative logical blocks, configurations, modules, circuits, means, logic, and algorithm operations described in relation to the exemplary embodiments additionally disclosed herein may be implemented by electronic hardware, computer software, or in a combination of electronic hardware and computer software. In order to clearly exemplify interchangeability of hardware and software, the various illustrative components, blocks, configurations, means, logic, modules, circuits, and operations have been generally described above in the functional aspects thereof. Whether the functionality is implemented as hardware or software depends on a specific application or design restraints given to the general system. Those skilled in the art may implement the functionality described by various methods for each of the specific applications. However, it shall not be construed that the determinations of the implementation deviate from the range of the contents of the present disclosure.

The description about the presented exemplary embodiments is provided so as for those skilled in the art to use or carry out the present disclosure. Various modifications of the exemplary embodiments will be apparent to those skilled in the art. General principles defined herein may be applied to other exemplary embodiments without departing from the scope of the present disclosure. Therefore, the present disclosure is not limited to the exemplary embodiments presented herein. The present disclosure shall be interpreted within the broadest meaning range consistent to the principles and new characteristics presented herein.

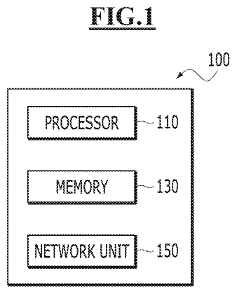

FIG. 1 is a block diagram of a computing device for placing a semiconductor cell according to an exemplary embodiment of the present disclosure.

The computing device 100 may include a processor 110, a memory 130, and a network unit 150.

The processor 110 may be constituted by one or more cores, and include processors for data analysis and deep learning, such as a central processing unit (CPU), a general purpose graphics processing unit (GPGPU), a tensor processing unit (TPU), etc., of the computing device. The processor 110 may read a computer program stored in the memory 130 and process data for machine learning according to an exemplary embodiment of the present disclosure. According to an exemplary embodiment of the present disclosure, the processor 110 may perform an operation for learning the neural network. The processor 110 may perform calculations for learning the neural network, which include processing of input data for learning in deep learning (DL), extracting a feature in the input data, calculating an error, updating a weight of the neural network using backpropagation, and the like. At least one of the CPU, the GPGPU, and the TPU of the processor 110 may process learning of the network function. For example, the CPU and the GPGPU may process the learning of the network function and data classification using the network function jointly. In addition, in an exemplary embodiment of the present disclosure, the learning of the network function and the data classification using the network function may be processed by using processors of a plurality of computing devices together. In addition, the computer program performed by the computing device according to an exemplary embodiment of the present disclosure may be a CPU, GPGPU, or TPU executable program.

In this case, as an exemplary embodiment, the processor 110 in the present disclosure may perform the following operation for optimizing a semiconductor design area which is a purpose of the present disclosure. First, the processor 110 may perform an operation for determining a placement location of a macro cell in a design area using a reinforcement learning model. Further, the processor 110 may perform an operation for determining candidate direction information for shifting the placement location of the macro cell determined by the reinforcement learning model (In this case, the candidate direction information may include a direction which faces an outside of the design area). Further, the processor 110 may perform an operation of shifting the placement location of the macro cell based on the determined candidate direction.

According to an exemplary embodiment of the present disclosure, the memory 130 may store any type of information generated or determined by the processor 110 or any type of information received by the network unit 150.

According to an exemplary embodiment of the present disclosure, the memory 130 may include at least one type of storage medium of a flash memory type storage medium, a hard disk type storage medium, a multimedia card micro type storage medium, a card type memory (for example, an SD or XD memory, or the like), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. The computing device 100 may operate in connection with a web storage performing a storing function of the memory 130 on the Internet. The description of the memory is just an example and the present disclosure is not limited thereto.

According to an exemplary embodiment of the present disclosure, the reinforcement learning model may be stored in the memory 130, and load and used by the processor 110.

According to an exemplary embodiment of the present disclosure, the design area may include a canvas (i.e., a continuous space or a canvas including the continuous space) in which points where semiconductor cells may be placed may be gradually placed in a predetermined space continuously or at a predetermined interval, and information a size of the canvas, a boundary of the canvas, and semiconductor cells placed in the canvas may be stored in the memory 130, and load and used by the processor 110.

According to an exemplary embodiment of the present disclosure, a candidate direction for shifting the placement location of the macro cell which may be determined by the reinforcement learning model may be stored in the memory 130, and load and used by the processor 110.

The network unit 150 according to an exemplary embodiment of the present disclosure may use an arbitrary type of known wired/wireless communication system.

The network unit 150 may receive information for the semiconductor design from an external system. For example, the network unit 150 may receive feature information and logical design information of the semiconductor cell from a semiconductor related database. In this case, the feature information and the logical design information received from the database may be data for learning or data for inference of the neural network model. The feature information and the logical design information of the semiconductor cell may include information of the above-mentioned example, but is not limited to the above-mentioned example, and may be variously configured within a scope which may be appreciated by those skilled in the art.

The network unit 150 may transmit and receive information processed by the processor 110, a user interface, and the like through communication with other terminals. For example, the network unit 150 may provide the user interface generated by the processor 110 to a client (e.g., a user terminal). In addition, the network unit 150 may receive an external input of a user applied to a client and transfer the external input to the processor 110. In this case, the processor 110 may process operations such as outputting, correcting, changing, adding, and the like of information provided through the user interface based on the external input of the user received from the network unit 150.

According to an exemplary embodiment of the present disclosure, the reinforcement learning model may be downloaded through the network unit 150 and stored in the memory 130, and load and used by the processor 110.

According to an exemplary embodiment of the present disclosure, the information the size of the canvas, the boundary of the canvas, and the semiconductor cells placed in the canvas may be downloaded through the network unit 150 and stored in the memory 130, and load and used by the processor 110.

Meanwhile, operations which are conducted by using the processor 110 of the present disclosure as a subject are conducted in an external computing device 100 other than one computing device 100, so a result may be shared through the network unit 150. In the present disclosure, for convenience of description, the exemplary embodiments may be expressed like an operation of a single processor 110. However, the exemplary embodiments are not limited thereto, and may be implemented by collaboration of various computing devices 100 as in a context described above.

Meanwhile, according to an exemplary embodiment of the present disclosure, the computing device 100 may include a server as a computing system that transmits and receives information through communication with the client. In this case, the client may be any type of terminal which may access the server. For example, the computing device 100 as the server may receive information for the semiconductor design from the external database, and generate a design result, and provide a user interface for a logical design result to the user terminal. At this time, the user terminal may output the user interface received from the computing device 100 as the server, and receive or process information through interaction with the user.

In an additional exemplary embodiment, the computing device 100 may also include any type of terminal that receives data resources generated by an arbitrary server and performs additional information processing.

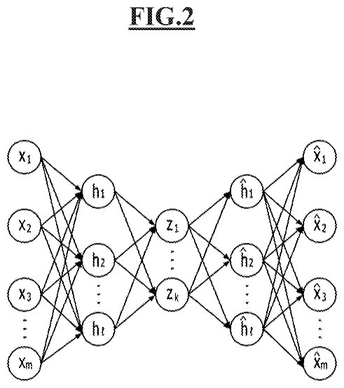

FIG. 2 is a schematic diagram illustrating a neural network according to the embodiment of the present disclosure.

A neural network model according to the embodiment of the present disclosure may include a neural network for logical design of semiconductors. The neural network may be formed of a set of interconnected calculation units which are generally referred to as “nodes”. The “nodes” may also be called “neurons”. The neural network consists of one or more nodes. The nodes (or neurons) configuring the neural network may be interconnected by one or more links.

In the neural network, one or more nodes connected through the links may relatively form a relationship of an input node and an output node. The concept of the input node is relative to the concept of the output node, and a predetermined node having an output node relationship with respect to one node may have an input node relationship in a relationship with another node, and a reverse relationship is also available. As described above, the relationship between the input node and the output node may be generated based on the link. One or more output nodes may be connected to one input node through a link, and a reverse case may also be valid.

In the relationship between an input node and an output node connected through one link, a value of the output node data may be determined based on data input to the input node. Herein, a link connecting the input node and the output node may have a weight. The weight is variable, and in order for the neural network to perform a desired function, the weight may be varied by a user or an algorithm. For example, when one or more input nodes are connected to one output node by links, respectively, a value of the output node may be determined based on values input to the input nodes connected to the output node and weights set in the link corresponding to each of the input nodes.

As described above, in the neural network, one or more nodes are connected with each other through one or more links to form a relationship of an input node and an output node in the neural network. A characteristic of the neural network may be determined according to the number of nodes and links in the neural network, a correlation between the nodes and the links, and a value of the weight assigned to each of the links. For example, when there are two neural networks in which the numbers of nodes and links are the same and the weight values between the links are different, the two neural networks may be recognized to be different from each other.

The neural network may consist of a set of one or more nodes. A subset of the nodes configuring the neural network may form a layer. Some of the nodes configuring the neural network may form one layer on the basis of distances from an initial input node. For example, a set of nodes having a distance of n from an initial input node may form n layers. The distance from the initial input node may be defined by the minimum number of links, which need to be passed to reach a corresponding node from the initial input node. However, the definition of the layer is arbitrary for the description, and a degree of the layer in the neural network may be defined by a different method from the foregoing method. For example, the layers of the nodes may be defined by a distance from a final output node.

The initial input node may mean one or more nodes to which data is directly input without passing through a link in a relationship with other nodes among the nodes in the neural network. Otherwise, the initial input node may mean nodes which do not have other input nodes connected through the links in a relationship between the nodes based on the link in the neural network. Similarly, the final output node may mean one or more nodes that do not have an output node in a relationship with other nodes among the nodes in the neural network. Further, the hidden node may mean nodes configuring the neural network, not the initial input node and the final output node.

In the neural network according to the embodiment of the present disclosure, the number of nodes of the input layer may be the same as the number of nodes of the output layer, and the neural network may be in the form that the number of nodes decreases and then increases again from the input layer to the hidden layer. Further, in the neural network according to another embodiment of the present disclosure, the number of nodes of the input layer may be smaller than the number of nodes of the output layer, and the neural network may be in the form that the number of nodes decreases from the input layer to the hidden layer. Further, in the neural network according to another embodiment of the present disclosure, the number of nodes of the input layer may be larger than the number of nodes of the output layer, and the neural network may be in the form that the number of nodes increases from the input layer to the hidden layer. The neural network according to another embodiment of the present disclosure may be the neural network in the form in which the foregoing neural networks are combined.

A deep neural network (DNN) may mean the neural network including a plurality of hidden layers, in addition to an input layer and an output layer. When the DNN is used, it is possible to recognize a latent structure of data. That is, it is possible to recognize latent structures of photos, texts, videos, voice, and music (for example, what objects are in the photos, what the content and emotions of the texts are, and what the content and emotions of the voice are). The DNN may include a convolutional neural network (CNN), a recurrent neural network (RNN), an auto encoder, Generative Adversarial Networks (GAN), a Long Short-Term Memory (LSTM), a transformer, a restricted Boltzmann machine (RBM), a deep belief network (DBN), a Q network, a U network, a Siamese network, a Generative Adversarial Network (GAN), and the like. The foregoing description of the deep neural network is merely illustrative, and the present disclosure is not limited thereto.

In the embodiment of the present disclosure, the network function may include an auto encoder. The auto encoder may be one type of artificial neural network for outputting output data similar to input data. The auto encoder may include at least one hidden layer, and the odd-numbered hidden layers may be disposed between the input/output layers. The number of nodes of each layer may decrease from the number of nodes of the input layer to an intermediate layer called a bottleneck layer (encoding), and then be expanded symmetrically with the decrease from the bottleneck layer to the output layer (symmetric with the input layer). The auto encoder may perform a nonlinear dimension reduction. The number of input layers and the number of output layers may correspond to the dimensions after preprocessing of the input data. In the auto encoder structure, the number of nodes of the hidden layer included in the encoder decreases as a distance from the input layer increases. When the number of nodes of the bottleneck layer (the layer having the smallest number of nodes located between the encoder and the decoder) is too small, the sufficient amount of information may not be transmitted, so that the number of nodes of the bottleneck layer may be maintained in a specific number or more (for example, a half or more of the number of nodes of the input layer and the like).

The neural network may be trained by at least one scheme of supervised learning, unsupervised learning, semi-supervised learning, and reinforcement learning. The training of the neural network may be a process of applying knowledge for the neural network to perform a specific operation to the neural network.

The neural network may be trained in a direction of minimizing an error of an output. In the training of the neural network, training data is repeatedly input to the neural network and an error of an output of the neural network for the training data and a target is calculated, and the error of the neural network is back-propagated in a direction from an output layer to an input layer of the neural network in order to decrease the error, and a weight of each node of the neural network is updated. In the case of the supervised learning, training data labelled with a correct answer (that is, labelled training data) is used, in each training data, and in the case of the unsupervised learning, a correct answer may not be labelled to each training data. That is, for example, the training data in the supervised learning for data classification may be data, in which category is labelled to each of the training data. The labelled training data is input to the neural network and the output (category) of the neural network is compared with the label of the training data to calculate an error. For another example, in the case of the unsupervised learning related to the data classification, training data that is the input is compared with an output of the neural network, so that an error may be calculated. The calculated error is back-propagated in a reverse direction (that is, the direction from the output layer to the input layer) in the neural network, and a connection weight of each of the nodes of the layers of the neural network may be updated according to the backpropagation. A change amount of the updated connection weight of each node may be determined according to a learning rate. The calculation of the neural network for the input data and the backpropagation of the error may configure a learning epoch. The learning rate is differently applicable according to the number of times of repetition of the learning epoch of the neural network. For example, at the initial stage of the learning of the neural network, a high learning rate is used to make the neural network rapidly secure performance of a predetermined level and improve efficiency, and at the latter stage of the learning, a low learning rate is used to improve accuracy.

In the training of the neural network, the training data may be generally a subset of actual data (that is, data to be processed by using the trained neural network), and thus an error for the training data is decreased, but there may exist a learning epoch, in which an error for the actual data is increased. Overfitting is a phenomenon, in which the neural network excessively learns training data, so that an error for actual data is increased. For example, a phenomenon, in which the neural network learning a cat while seeing a yellow cat cannot recognize cats, other than a yellow cat, as cats, is a sort of overfitting. Overfitting may act as a reason of increasing an error of a machine learning algorithm. In order to prevent overfitting, various optimizing methods may be used. In order to prevent overfitting, a method of increasing training data, a regularization method, a dropout method of inactivating a part of nodes of the network during the training process, a method using a bath normalization layer, and the like may be applied.

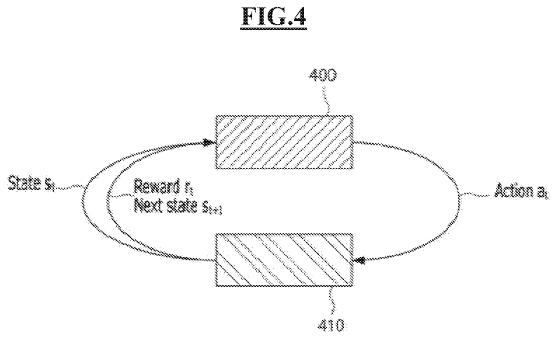

The reinforcement learning model may include an agent which is a neural network model. In one embodiment, the processor 110 may use reinforcement learning model to determine a placement location of a macro-element on a design region. (A more detailed description of said reinforcement learning model will be described later with reference to FIG. 4).

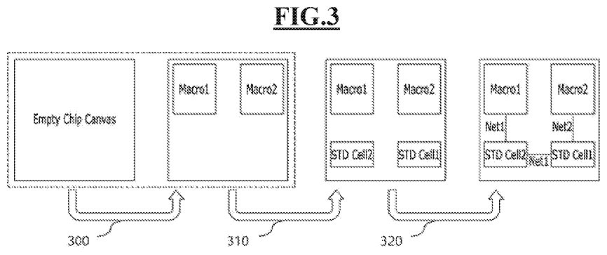

FIG. 3 is a conceptual view illustrating a basic semiconductor design process.

Prior to the description, the term canvas used in the present disclosure may be understood as a type of design area where cells are placed. In the present disclosure, the expression canvas is often used for the convenience of description in overall, but it may be understood as the design area in the same sense as the context mentioned above. In other words, even if it is expressed as the canvas, it may not be limited to the canvas, but also include other things that may correspond to the design area.

The design of the semiconductor requires Netlist information that defines characteristics of semiconductor cells and a connection relationship between the cells. In the netlist information, the semiconductor cells are divided into relatively large macro cells and relatively small standard cells. The macro cell has no separate specification for a size, and is constituted by millions of transistors, which are usually larger than the standard cell. For example, the macro cell includes an SRAM or CPU core. The standard cell refers to a small unit of cell having a basic function, which is constituted by one or more transistors. The standard cell provides a storage function such as a simple logical operation (e.g., AND, OR, XOR) or a flip-flop, and also provide a more complicated function such as a 2-bit full adder or a multi-D input flip-flop. The standard cell has a specification for the size unlike the macro cell.

FIG. 3 is a schematic view illustrating a basic semiconductor design process.

Referring to FIG. 3, a process for designing the semiconductor may be divided into three steps. First, a floorplan step 300 is performed in which a macro cell which is a relatively large cell is placed in an empty canvas. Next, a placement step 310 is performed in which the macro cell is placed in the canvas and a standard cell is placed in a remaining space. Last, a routing step 320 is performed in which the macro cell and the standard cell placed in the canvas are physically connected through a wire. As an exemplary embodiment according to the purpose of the present disclosure, operations of placing the semiconductor cell by optimizing the design area may be made in the above-mentioned floorplan step. However, this is just a preferred example, and the present disclosure is not limited thereto, and may be used at various viewpoints.

Whether a good design is made through the above-mentioned process may be evaluated through an evaluation item called PPA. The PPA is an abbreviation of power, performance, and area. According to the PPA, the semiconductor design aims to obtain low production cost with a small area, i.e., a high integrity while showing lower power consumption and high performance. In order to optimize the PPA according to the goal, a length of the wire connecting the semiconductor cells should be reduced. When the length of the wire connecting the cells is short, the reach of an electric signal may be accelerated, thermal energy generated due to resistance of the wire may be reduced, and power loss may be reduced. Moreover, apparently, when the overall use of the wire is reduced, the density of the cells increases, which also reduces an area of a required canvas. In this case, the density may decrease as there are more so-called dead spaces in which the wire and the standard cell included in the design area may not be placed. Therefore, in order to design the semiconductor well, it is necessary to minimize the dead space to optimize indicators related to the PPA mentioned above. As an exemplary embodiment of the present disclosure, when the processor 110 places the semiconductor cells in the design area using a reinforcement learning model, the reinforcement learning model may include an agent reinforced-learned to place the macro cell by considering PPA optimization.

FIG. 4 is a conceptual view for describing a reinforcement learning process according to an exemplary embodiment of the present disclosure.

The reinforcement learning model as a kind of neural network model may mean a model of determining a possible option as an action based on a state which an agent 400 acquires from a surrounding environment 410, and a series of processes may be referred to as one episode, and the reinforcement learning model may be gradually trained based on a reward which is a feedback calculated for an action selected every episode. That is, the reinforcement learning may be appreciated as learning through trial and error in that the reward is given for the determination (i.e., action).

According to an exemplary embodiment of the present disclosure, the processor 110 may determine a placement location of the macro cell in the design area using the reinforcement learning model. For example, the action of the reinforcement learning model may include an action of determining the placement location of the macro cell to maximize the reward. In this case, the reward may be calculated based on at least one of the length of the wire connecting the semiconductor cells placed in the canvas (design area) through the action, and a congestion or connection of the semiconductor cells placed in the canvas through the action. For example, the reward may be computed by a weighed sum of the length of the wire and the congestion, and implemented in the form of a negative reward. According to an exemplary embodiment of the present disclosure, the reward may be calculated based on individual macro-unit placement or macro group-unit placement. In an exemplary embodiment, the reward may be computed by a weighed sum of the connection (e.g., the length of the wire) and the congestion between the semiconductor cells computed by considering the placement location of the macro group to be placed. However, this is just one example of calculating the reward, and the present disclosure is not limited thereto, and the reward may be calculated by various methods.

According to an exemplary embodiment of the present disclosure, the processor 110 may determine candidate directions for shifting the placement location of the macro cell determined by the reinforcement learning model, and shift the placement location of the macro cell based on the determined candidate directions. Here, the placement location (to be shifted) determined by the reinforcement learning model may be a “final placement location according to the reinforcement learning result” or a “placement location determined during reinforcement learning process”. Further, the “final placement location according to the reinforcement learning result” may be a placement location which the reinforcement learning model finally determines after completing the reinforcement learning. Further, the “placement location determined during the reinforcement learning process” may be a location which the reinforcement learning model determines as a candidate of the placement in the process of the reinforcement learning. Further, the “placement location determined during the reinforcement learning process” may include a placement location associated with an episode related to calculation of a reward of the reinforcement learning. Meanwhile, when the placement location to be shifted is the “final placement location according to the reinforcement learning result”, the “shift of the placement location for the macro cell” according to an exemplary embodiment of the present disclosure is performed as postprocessing of the reinforcement learning, and does not influence reward calculation of the reinforcement learning. On the contrary, when the placement location to be shifted is the “placement location determined during the reinforcement learning process”, the “shift of the placement location for the macro cell” according to an exemplary embodiment of the present disclosure may directly influence the reward calculation of the reinforcement learning. In other words, in this case, the reward of the reinforcement learning may be calculated by considering the shift of the location of the macro cell based on the determined candidate direction. For example, the reinforcement learning model may shift, when calculating a reward relate to placement of a specific macro cell (e.g., a 10-th placed macro cell) in any episode, an initial placement location determined for the specific macro cell (that is, shift the initial placement location of the specific macro cell based on the candidate direction determined according to an exemplary embodiment of the present disclosure), and calculate the reward based on the shifted placement location.

Additionally, the placement location of the macro cell determined by the reinforcement learning model may include a cell-unit placement location or a placement location of a group unit including a plurality of macro cells. That is, the processor 110 may determine the placement location by the unit of an individual macro cell or determine the placement location by the unit of the macro group when placing the macro cell using the reinforcement learning model. Further, the processor 110 may shift the placement location by the unit of an individual macro cell or shift the placement location by the unit of the macro group even when shifting the placement location (that is, shift the placement location of the macro cell based on the determined candidate direction) according to an exemplary embodiment of the present disclosure.

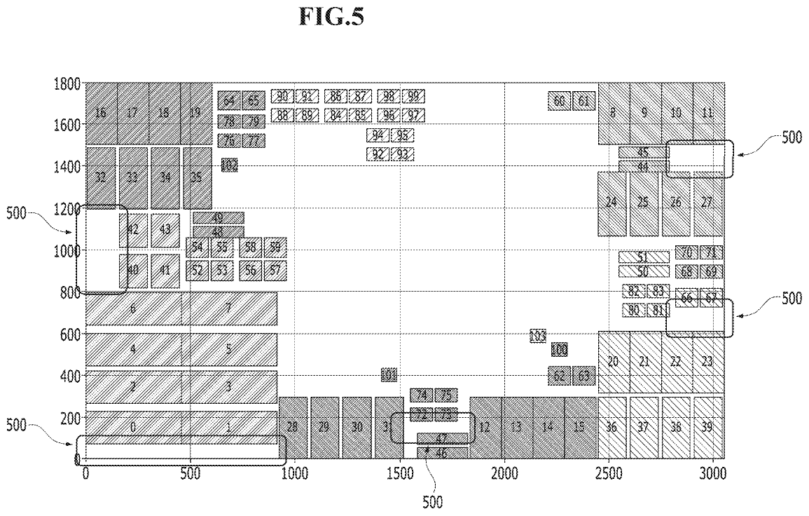

FIG. 5 is an exemplary diagram illustrating placement of a semiconductor cell which needs to be optimized.

In an exemplary embodiment, when the processor 110 determines the placement location of the macro cell in the design area using the reinforcement learning model, an isolated space may be generated in which another macro cell may not be placed any longer as represented by reference numeral 500 of FIG. 5. In the present disclosure, such a space may be referred to as an exemplary dead space, and the dead space may apparently exert a negative influence the PPA related to the performance of the semiconductor design. Meanwhile, the dead space may include various types of spaces which may exert the bad influence on the PPA in the process of the semiconductor design in addition to such an example. Therefore, an optimization process of removing the dead space such as reference numeral 500 may be required for a good design of the semiconductor, and the dead space may be removed by shifting the placement locations of the macro cells.

As an exemplary embodiment therefor, the processor 110 may determine the candidate direction for shifting the determined placement location of the macro cell, and shift the placement location of the macro cell based on the determined candidate direction.

In relation to the shift of the placement location, when the macro cells are in close contact in an outer direction of the canvas, an environment in the canvas may be created so that the standard cell is easily placed in a central area of the canvas as the density of the macro cells increases. Accordingly, the candidate direction determined according to an exemplary embodiment of the present disclosure may be configured to face the outer direction of the canvas. In this case, the direction facing the outside may adopt any one of a direction facing a corner of the canvas or a direction facing an edge of the canvas. In this case, in the present disclosure, for convenience of description, an exemplary embodiment in which the location of the macro cell is shifted in the direction facing the corner may be referred to as a ‘first location shift exemplary embodiment’ and an exemplary embodiment in which the location of the macro group is shifted in the direction facing the edge may be referred to as a ‘second location shift exemplary embodiment’. According to an exemplary embodiment, the processor 110 may optimize a canvas in which the macro cell is placed using at least one of the ‘first location shift exemplary embodiment’ and the ‘second location shift exemplary embodiment’.

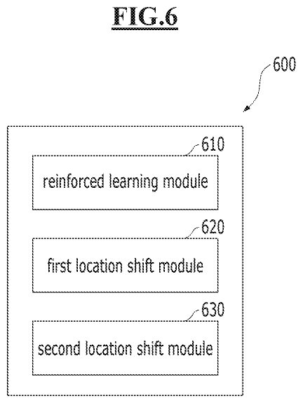

FIG. 6 is a block diagram illustrating modules according to an exemplary embodiment of the present disclosure.

Referring to FIG. 6, the processor 110 may use at least one of a ‘reinforcement learning module’ 610, a ‘first location shift module’ 620, and a ‘second location shift module’ 630 in implementing the exemplary embodiments of the present disclosure. As an exemplary embodiment related thereto, the processor 110 may determine the placement location of the macro cell in the design area using the reinforcement learning module 610. Further, the processor 110 may shift the location of the macro cell placed in the canvas in a closest corner direction using the first location shift module 620. Further, the processor 110 may shift the placement location the macro group placed in the canvas in a direction facing an edge of the canvas closest to a bounding box of the macro group and an edge of the canvas second closest to the bounding box using the second location shift module 630 (A detailed description and an example for the first location shift module 620 and the second location shift module 630 will be described later in detail).

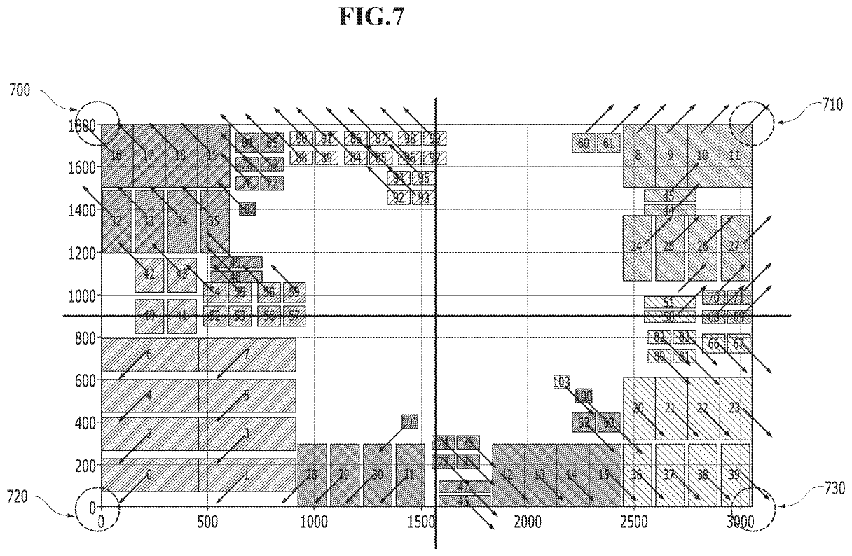

FIG. 7 is an exemplary diagram of a method for shifting a location of a semiconductor cell by a first location shift module according to an exemplary embodiment of the present disclosure.

In the above description, it is described that in designing the semiconductor, the isolated area may be generated in which the semiconductor cells such as reference numeral 500 may not be placed, and the isolated area needs to be optimized (that is, the placement location of the macro cell needs to be shifted). As an exemplary embodiment related to the optimization, the processor 110 may divide the canvas into four areas having the same size, which include corners, respectively, i.e., a quadrant by using the first location shift module 620. Further, the processor 110 may identify to which quadrant among divided quadrants each macro cell placed in the canvas belongs using the first location shift module 620. Further, the processor 110 may determine the candidate direction so as for each macro cell placed in the canvas to face a corner included in the quadrant to which each macro cell belongs using the first location shift module 620, and shift the placement location of the macro cell based on the determined candidate direction. For example, referring to FIG. 7, the processor 110 may place 99 macro cells in a canvas having a size of approximately 3000×1800 using the reinforcement learning module 610. Further, the processor 110 may divide the canvas into an area related to a top left corner 700, an area related to a top right corner 710, an area related to a bottom left corner 720, and an area related to a bottom right corner 730 using the first location shift module 620. Further, the processor 110 may identify macro cells included in the canvas into the area related to the top left corner 700, the area related to the top right corner 710, the area related to the bottom left corner 720, and the area related to the bottom right corner 730, respectively using the first location shift module 620. Finally, the processor 110 may determine the candidate direction so as for each macro cell placed in the canvas to face a corner included in the area (quadrant) to which each macro cell belongs in a predetermined order or a random order using the first location shift module 620, and shift the placement location of the macro cell based on the determined candidate direction. In this case, the predetermined order may be related to an order of placing a predetermined semiconductor cell.

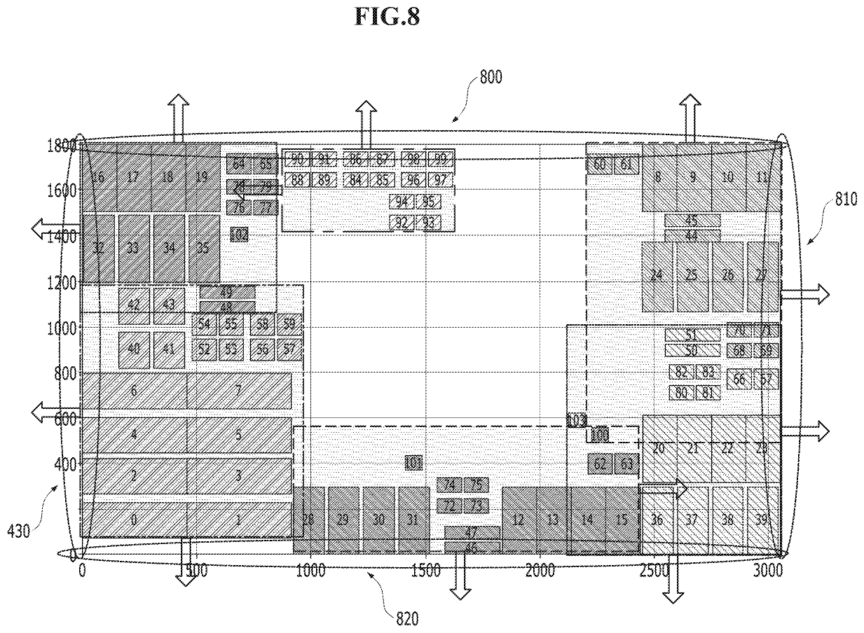

FIG. 8 is an exemplary diagram of a method for shifting a location of a semiconductor cell by a second location shift module according to an exemplary embodiment of the present disclosure.

In the above description, it is described that in designing the semiconductor, the isolated area may be generated in which the semiconductor cells such as reference numeral 500 may not be placed, and the isolated area needs to be optimized. In this case, as in an exemplary embodiment related to FIG. 7, it may be more advantageous for the computation to shift the placement location by binding the macro cells into the macro group than to shift the placement location of each macro cell. As an exemplary embodiment of the present disclosure related thereto, the processor 110 may identify the macro group of the macro cells to be placed in the canvas using the second location shift module 630. Further, the processor 110 may identify a bounding box of the identified macro groups using the second location shift module 630, and determine a direction in which respective macro groups are to be location-shifted as the direction facing the edge based on the bounding box. In this case, the direction facing the edge may include at least one direction of a direction facing an edge closest to the bounding box of the macro group includes the macro cells among the edges of the canvas or a direction facing an edge second closest. For example, referring to FIG. 8, the processor 110 may place 99 macro cells in a canvas having a size of approximately 3000×1800 using the reinforcement learning module 610. The processor 110 may identify seven macro groups of the macro cells to be placed in the canvas using the second location shift module 630. The processor 110 may identify each of bounding boxes of seven identified macro groups using the second location shift module 630. The processor 110 measures distances between the bounding boxes of seven macro groups, and a top edge 800, a right edge 810, a bottom edge 820, and a left edge 830, respectively using the second location shift module 630 to determine an edge first closest and an edge second closest as the candidate direction for shifting the placement location of the macro group for every seven identified macro groups. Thereafter, the processor 110 may shift the placement location of the macro group based on the determined candidate direction using the second location shift module 630. In this case, since two determined candidate directions are present for each macro group, an order of two candidate directions is determined and the placement location of the macro group needs to be shifted according to the determined order. For example, when the determined candidate direction of the first macro group is a top direction and a left direction, the processor 110 determines the top direction as #1 and the left direction as #2 to first shift the placement location of the first macro group to the top direction, and then shift the placement location of the first macro group of which placement location is shifted to the left direction.

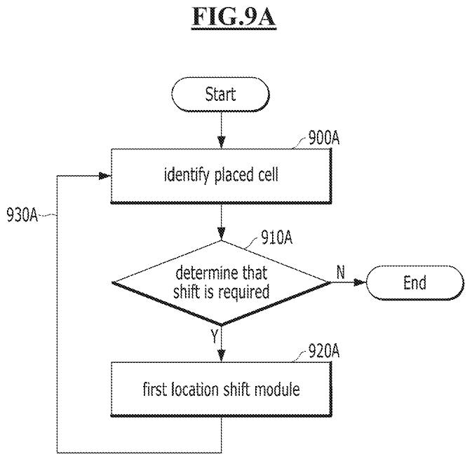

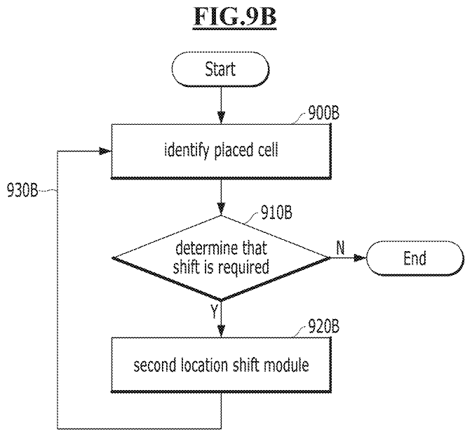

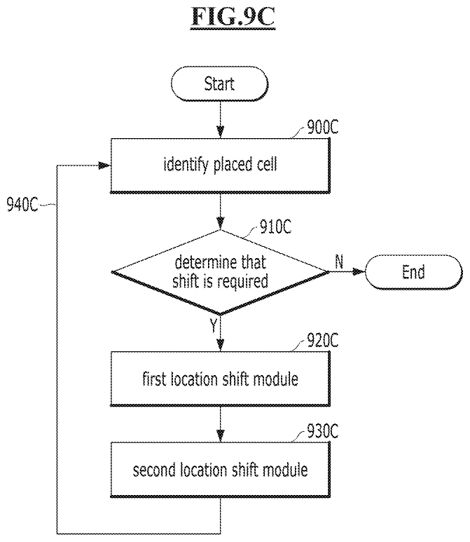

FIG. 9A is a flowchart of a method for optimizing a semiconductor design using a first location shift module according to an exemplary embodiment of the present disclosure.

From now on, an exemplary embodiment for a method for optimizing, by the processor 110, the semiconductor design by shifting the location of the macro cell using the first location shift module is disclosed. Referring to FIG. 9A, the processor 110 may perform a step 900a of identifying a macro cell of which placement location is determined in advance in the canvas or macro cells of which placement locations are determined through the reinforcement learning model. Following step 900a above, the processor 110 may perform a step 910a of determining whether the location of the cell needs to be shifted based on the canvas and the macro cells of which placement locations in the canvas are determined. In step 910a above, when it is determined that the locations of the macro cells placed in the canvas need to be shifted, the processor 110 may shift the placement locations of the macro cells included in the canvas using the first location shift module 920a. After step 920a above, the processor 110 returns to step 900a (930a) again to identify the canvas and the macro cells of which placement locations are shifted (900a), and determine whether the placement locations of the macro cells need to be shifted again (910a). That is, the processor 110 may shift the placement locations of the macro cells in the canvas using the first location shift module 920a repeatedly until the placement locations of the macro cells included in the canvas need not be shifted.

FIG. 9B is a flowchart of a method for optimizing the semiconductor design using a second location shift module according to an exemplary embodiment of the present disclosure.

From now on, an exemplary embodiment for a method for optimizing, by the processor 110, the semiconductor design by shifting the location of the macro cell using the second location shift module is disclosed. Referring to FIG. 9B, the processor 110 may perform a step 900b of identifying a macro cell and a macro group of which placement location is determined in advance in the canvas or the macro cell and the macro group of which placement locations are determined through the reinforcement learning model. Following step 900b above, the processor 110 may perform a step 910b of determining whether the location of the cell needs to be shifted based on the canvas and the macro groups of which placement locations in the canvas are determined. In step 910b above, when it is determined that the locations of the macro groups placed in the canvas need to be shifted, the processor 110 may shift the placement locations of the macro groups included in the canvas using the second location shift module 920b. After step 920b above, the processor 110 returns to step 900b (930b) again to identify the canvas and the macro groups of which placement locations are shifted (900b), and determine whether the placement locations of the macro groups need to be shifted again (910b). That is, the processor 110 may shift the placement locations of the macro groups in the canvas using the second location shift module 920b repeatedly until the placement locations of the macro groups included in the canvas need not be shifted.

FIG. 9C is a flowchart of a method for optimizing the semiconductor design using the first and second location shift modules according to an exemplary embodiment of the present disclosure.

From now on, an exemplary embodiment for a method for optimizing, by the processor 110, the semiconductor design by shifting the location of the macro cell using the first location shift module and the second location shift module is disclosed. Referring to FIG. 9C, the processor 110 may perform a step 900c of identifying a macro cell and a macro group of which placement location is determined in advance in the canvas or the macro cell and the macro group of which placement locations are determined through the reinforcement learning model. Following step 900C above, the processor 110 may perform a step 910c of determining whether the location of the cell needs to be shifted based on the canvas and the macro cells and the macro groups of which placement locations in the canvas are determined. In step 910c above, when it is determined that the locations of the macro cells and the macro groups placed in the canvas need to be shifted, the processor 110 may shift the placement locations of the macro cells included in the canvas using a first location shift module 920c. After step 920c above, the processor 110 may shift the placement locations of the macro groups included in the canvas using a second location shift module 930c. After step 930c above, the processor 110 returns to step 900c (940c) again to identify the canvas and the macro cells and the macro groups of which placement locations are shifted (900c), and determine whether the placement locations of the macro cells and the macro groups need to be shifted again (910c). That is, the processor 110 may shift the placement locations of the macro groups in the canvas using the first location shift module 920c and the second location shift module 930c repeatedly until the placement locations of the macro cells and the macro groups included in the canvas need not be shifted. In this case, the order of the first location shift module and the second location shift module may be replaced. That is, both the first location shift module->the second location shift module and the second location shift module->the first location shift module may be performed.

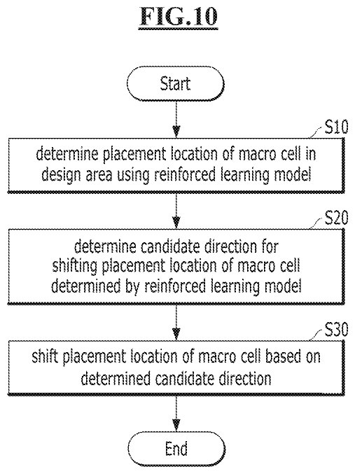

FIG. 10 is a flowchart illustrating a schematic sequence for a method for placing a semiconductor cell according to an exemplary embodiment of the present disclosure. A flow of schematic steps according to an exemplary embodiment of the present disclosure is descried with reference to FIG. 10.

The steps may include a step S10 of determining, by a processor 110, a placement location of a macro cell in a design area using a reinforcement learning model, a step S20 of determining, by the processor 110, a candidate direction for shifting the placement location of the macro cell determined by the reinforcement learning model, and a step S30 of shifting, by the processor 110, the placement location of the macro cell based on the determined candidate direction.

In this case, commonly to the exemplary embodiments, the determined candidate direction may include a direction facing the outside of the design area and the direction facing the outside may include at least one of a direction facing a corner of the design area or a direction facing an edge of the design area (As mentioned above, the design area may include a canvas area for placing the semiconductor cell).

The direction facing the outside of the design area may be divided into 1) “the direction facing the corner of the canvas” and 2) “the direction facing the edge of the canvas”, and in relation to 1), the direction facing the corner may include a direction facing a corner closest to the placement location of the macro cell among the plurality of corners of the canvas, and may be determined based on identifying a quadrant includes the macro cells among the quadrants of the canvas. In relation to 2), the direction facing the edge may be determined based on the bounding box of the macro group includes the macro cells. In this case, the direction facing the edge may include at least one direction of a direction facing an edge closest to the bounding box of the macro group includes the macro cells among the edges of the canvas or a direction facing an edge second closest.

In this case, as an additional exemplary embodiment using both 1) and 2), in relation to step S20 above, the step of determining the candidate direction by the processor 110 may include a step of determining a plurality of candidate directions for shifting the placement location of the macro cell, and in relation to step S30 above, the step of shifting the placement location of the macro cell by the processor 110 may include a step of shifting, by the processor 110, the placement location of the macro cell based on the plurality of determined candidate directions. In this case, the plurality of determined candidate directions may include a direction facing one corner among the plurality of corners of the design area, and a direction facing one edge among the plurality of edges of the design area. Further, the plurality of determined candidate directions may include two or more directions facing two or more edges among the plurality of edges of the design area. Further, the plurality of determined candidate directions may include the direction facing one corner among the plurality of corners of the design area, and two or more directions facing two or more edges among the plurality of edges of the design area. In this case, the direction facing one corner among the plurality of corners of the design area may be determined by the unit of an individual macro cell. Further, the directions facing two or more edges among the plurality of edges of the design area may be determined by the unit of the macro group including a plurality of macro cells.

In addition to the above-described effects, when the optimization method according to an exemplary embodiment of the present disclosure is used, timing performance may be improved, which is performance which becomes important in designing semiconductor cell placement. The timing performance may be evaluated through an indicator called total negative slack (TNS).

Table 1 below is a table which experiments and compares TNS before optimizing three canvases and TNS after optimizing three canvases in optimizing the semiconductor design using the methods according to an exemplary embodiment of the present disclosure.

TABLE 1

| | TNS before | TNS after | Improvement |
|---|---|---|---|
| Classification | optimization | optimization | amount |
| Case-1 | 3191 | 1011.5 | 68.3% |
| Case-2 | 7134.4 | 1417.1 | 80.24% |
| Case-3 | 3000 | 1001.4 | 66.62% |

When Table 1 above is confirmed, it can be seen that in the case of Case-1 to Case-3 using the optimization method according to an exemplary embodiment of the present disclosure, TNS numerical values are improved by 68.3%, 80.24%, and 66.62%, respectively as compared with TNS numerical values before optimization (it may be appreciated that the timing performance is improved as the TNS is the lower). Accordingly, when the optimization method according to an exemplary embodiment of the present disclosure is used, it may be confirmed that the timing performance is enhanced as compared with the timing performance before using the optimization method.

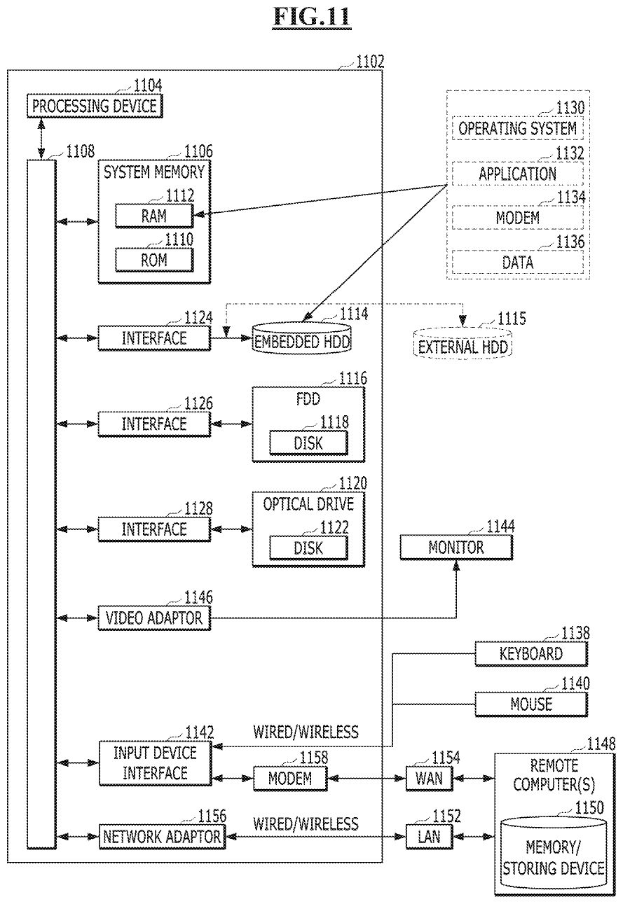

FIG. 11 is a conceptual view of a computing environment according to an exemplary embodiment of the present disclosure.

Referring to FIG. 11, disclosed is a computer readable medium storing a data structure according to an exemplary embodiment of the present disclosure.

The data structure may refer to organization, management, and storage of data that enable efficient access and modification of data. The data structure may refer to organization of data for solving a specific problem (for example, data search, data storage, and data modification in the shortest time). The data structure may also be defined with a physical or logical relationship between the data elements designed to support a specific data processing function. A logical relationship between data elements may include a connection relationship between user defined data elements. A physical relationship between data elements may include an actual relationship between the data elements physically stored in a computer readable storage medium (for example, a permanent storage device). In particular, the data structure may include a set of data, a relationship between data, and a function or a command applicable to data. Through the effectively designed data structure, the computing device may perform a calculation while minimally using resources of the computing device. In particular, the computing device may improve efficiency of calculation, reading, insertion, deletion, comparison, exchange, and search through the effectively designed data structure.

The data structure may be divided into a linear data structure and a non-linear data structure according to the form of the data structure. The linear data structure may be the structure in which only one data is connected after one data. The linear data structure may include a list, a stack, a queue, and a deque. The list may mean a series of dataset in which order exists internally. The list may include a linked list. The linked list may have a data structure in which data is connected in a method in which each data has a pointer and is linked in a single line. In the linked list, the pointer may include information about the connection with the next or previous data. The linked list may be expressed as a single linked list, a double linked list, and a circular linked list according to the form. The stack may have a data listing structure with limited access to data. The stack may have a linear data structure that may process (for example, insert or delete) data only at one end of the data structure. The data stored in the stack may have a data structure (Last In First Out, LIFO) in which the later the data enters, the sooner the data comes out. The queue is a data listing structure with limited access to data, and may have a data structure (First In First Out, FIFO) in which the later the data is stored, the later the data comes out, unlike the stack. The deque may have a data structure that may process data at both ends of the data structure.

The non-linear data structure may be the structure in which the plurality of data is connected after one data. The non-linear data structure may include a graph data structure. The graph data structure may be defined with a vertex and an edge, and the edge may include a line connecting two different vertexes. The graph data structure may include a tree data structure. The tree data structure may be the data structure in which a path connecting two different vertexes among the plurality of vertexes included in the tree is one. That is, the tree data structure may be the data structure in which a loop is not formed in the graph data structure.

The data structure may include a neural network. Further, the data structure including the neural network may be stored in a computer readable medium. The data structure including the neural network may also include preprocessed data for processing by the neural network, data input to the neural network, a weight of the neural network, a hyper-parameter of the neural network, data obtained from the neural network, an active function associated with each node or layer of the neural network, and a loss function for training of the neural network. The data structure including the neural network may include predetermined configuration elements among the disclosed configurations. That is, the data structure including the neural network may include the entirety or a predetermined combination of pre-processed data for processing by neural network, data input to the neural network, a weight of the neural network, a hyper parameter of the neural network, data obtained from the neural network, an active function associated with each node or layer of the neural network, and a loss function for training the neural network. In addition to the foregoing configurations, the data structure including the neural network may include predetermined other information determining a characteristic of the neural network. Further, the data structure may include all type of data used or generated in a computation process of the neural network, and is not limited to the foregoing matter. The computer readable medium may include a computer readable recording medium and/or a computer readable transmission medium. The neural network may be formed of a set of interconnected calculation units which are generally referred to as “nodes”. The “nodes” may also be called “neurons.” The neural network consists of one or more nodes.

The data structure may include data input to the neural network. The data structure including the data input to the neural network may be stored in the computer readable medium. The data input to the neural network may include training data input in the training process of the neural network and/or input data input to the training completed neural network. The data input to the neural network may include data that has undergone pre-processing and/or data to be pre-processed. The pre-processing may include a data processing process for inputting data to the neural network. Accordingly, the data structure may include data to be pre-processed and data generated by the pre-processing. The foregoing data structure is merely an example, and the present disclosure is not limited thereto.

The data structure may include a weight of the neural network (in the present specification, weights and parameters may be used with the same meaning), Further, the data structure including the weight of the neural network may be stored in the computer readable medium. The neural network may include a plurality of weights. The weight is variable, and in order for the neural network to perform a desired function, the weight may be varied by a user or an algorithm. For example, when one or more input nodes are connected to one output node by links, respectively, the output node may determine a data value output from the output node based on values input to the input nodes connected to the output node and the weight set in the link corresponding to each of the input nodes. The foregoing data structure is merely an example, and the present disclosure is not limited thereto.

For a non-limited example, the weight may include a weight varied in the neural network training process and/or the weight when the training of the neural network is completed. The weight varied in the neural network training process may include a weight at a time at which a training cycle starts and/or a weight varied during a training cycle. The weight when the training of the neural network is completed may include a weight of the neural network completing the training cycle. Accordingly, the data structure including the weight of the neural network may include the data structure including the weight varied in the neural network training process and/or the weight when the training of the neural network is completed. Accordingly, it is assumed that the weight and/or a combination of the respective weights are included in the data structure including the weight of the neural network. The foregoing data structure is merely an example, and the present disclosure is not limited thereto.

The data structure including the weight of the neural network may be stored in the computer readable storage medium (for example, a memory and a hard disk) after undergoing a serialization process. The serialization may be the process of storing the data structure in the same or different computing devices and converting the data structure into a form that may be reconstructed and used later. The computing device may serialize the data structure and transceive the data through a network. The serialized data structure including the weight of the neural network may be reconstructed in the same or different computing devices through deserialization. The data structure including the weight of the neural network is not limited to the serialization. Further, the data structure including the weight of the neural network may include a data structure (for example, in the non-linear data structure, B-Tree, Trie, m-way search tree, AVL tree, and Red-Black Tree) for improving efficiency of the calculation while minimally using the resources of the computing device. The foregoing matter is merely an example, and the present disclosure is not limited thereto.

The data structure may include a hyper-parameter of the neural network. The data structure including the hyper-parameter of the neural network may be stored in the computer readable medium. The hyper-parameter may be a variable varied by a user. The hyper-parameter may include, for example, a learning rate, a cost function, the number of times of repetition of the training cycle, weight initialization (for example, setting of a range of a weight value to be weight-initialized), and the number of hidden units (for example, the number of hidden layers and the number of nodes of the hidden layer). The foregoing data structure is merely an example, and the present disclosure is not limited thereto.

The present disclosure has been described as being generally implementable by the computing device, but those skilled in the art will appreciate well that the present disclosure is combined with computer executable commands and/or other program modules executable in one or more computers and/or be implemented by a combination of hardware and software.

In general, a program module includes a routine, a program, a component, a data structure, and the like performing a specific task or implementing a specific abstract data form. Further, those skilled in the art will well appreciate that the method of the present disclosure may be carried out by a personal computer, a hand-held computing device, a microprocessor-based or programmable home appliance (each of which may be connected with one or more relevant devices and be operated), and other computer system configurations, as well as a single-processor or multiprocessor computer system, a mini computer, and a main frame computer.

The embodiments of the present disclosure may be carried out in a distribution computing environment, in which certain tasks are performed by remote processing devices connected through a communication network. In the distribution computing environment, a program module may be located in both a local memory storage device and a remote memory storage device.

The computer generally includes various computer readable media. The computer accessible medium may be any type of computer readable medium, and the computer readable medium includes volatile and non-volatile media, transitory and non-transitory media, and portable and non-portable media. As a non-limited example, the computer readable medium may include a computer readable storage medium and a computer readable transport medium. The computer readable storage medium includes volatile and non-volatile media, transitory and non-transitory media, and portable and non-portable media constructed by a predetermined method or technology, which stores information, such as a computer readable command, a data structure, a program module, or other data. The computer readable storage medium includes a RAM, a Read Only Memory (ROM), an Electrically Erasable and Programmable ROM (EEPROM), a flash memory, or other memory technologies, a Compact Disc (CD)-ROM, a Digital Video Disk (DVD), or other optical disk storage devices, a magnetic cassette, a magnetic tape, a magnetic disk storage device, or other magnetic storage device, or other predetermined media, which are accessible by a computer and are used for storing desired information, but is not limited thereto.

The computer readable transport medium generally implements a computer readable command, a data structure, a program module, or other data in a modulated data signal, such as a carrier wave or other transport mechanisms, and includes all of the information transport media. The modulated data signal means a signal, of which one or more of the characteristics are set or changed so as to encode information within the signal. As a non-limited example, the computer readable transport medium includes a wired medium, such as a wired network or a direct-wired connection, and a wireless medium, such as sound, Radio Frequency (RF), infrared rays, and other wireless media. A combination of the predetermined media among the foregoing media is also included in a range of the computer readable transport medium.

An illustrative environment 1100 including a computer 1102 and implementing several aspects of the present disclosure is illustrated, and the computer 1102 includes a processing device 1104, a system memory 1106, and a system bus 1108. The system bus 1108 connects system components including the system memory 1106 (not limited) to the processing device 1104. The processing device 1104 may be a predetermined processor among various commonly used processors. A dual processor and other multi-processor architectures may also be used as the processing device 1104.

The system bus 1108 may be a predetermined one among several types of bus structure, which may be additionally connectable to a local bus using a predetermined one among a memory bus, a peripheral device bus, and various common bus architectures. The system memory 1106 includes a ROM 1110, and a RAM 1112. A basic input/output system (BIOS) is stored in a non-volatile memory 1110, such as a ROM, an EPROM, and an EEPROM, and the BIOS includes a basic routing helping a transport of information among the constituent elements within the computer 1102 at a time, such as starting. The RAM 1112 may also include a high-rate RAM, such as a static RAM, for caching data.

The computer 1102 also includes an embedded hard disk drive (HDD) 1114 (for example, enhanced integrated drive electronics (EIDE) and serial advanced technology attachment (SATA))—the embedded HDD 1114 being configured for exterior mounted usage within a proper chassis (not illustrated)—a magnetic floppy disk drive (FDD) 1116 (for example, which is for reading data from a portable diskette 1118 or recording data in the portable diskette 1118), and an optical disk drive 1120 (for example, which is for reading a CD-ROM disk 1122, or reading data from other high-capacity optical media, such as a DVD, or recording data in the high-capacity optical media). A hard disk drive 1114, a magnetic disk drive 1116, and an optical disk drive 1120 may be connected to a system bus 1108 by a hard disk drive interface 1124, a magnetic disk drive interface 1126, and an optical drive interface 1128, respectively. An interface 1124 for implementing an outer mounted drive includes, for example, at least one of or both a universal serial bus (USB) and the Institute of Electrical and Electronics Engineers (IEEE) 1394 interface technology.

The drives and the computer readable media associated with the drives provide non-volatile storage of data, data structures, computer executable commands, and the like. In the case of the computer 1102, the drive and the medium correspond to the storage of random data in an appropriate digital form. In the description of the computer readable media, the HDD, the portable magnetic disk, and the portable optical media, such as a CD, or a DVD, are mentioned, but those skilled in the art will well appreciate that other types of computer readable media, such as a zip drive, a magnetic cassette, a flash memory card, and a cartridge, may also be used in the illustrative operation environment, and the predetermined medium may include computer executable commands for performing the methods of the present disclosure.

A plurality of program modules including an operation system 1130, one or more application programs 1132, other program modules 1134, and program data 1136 may be stored in the drive and the RAM 1112. An entirety or a part of the operation system, the application, the module, and/or data may also be cached in the RAM 1112. It will be well appreciated that the present disclosure may be implemented by several commercially usable operation systems or a combination of operation systems.

A user may input a command and information to the computer 1102 through one or more wired/wireless input devices, for example, a keyboard 1138 and a pointing device, such as a mouse 1140. Other input devices (not illustrated) may be a microphone, an IR remote controller, a joystick, a game pad, a stylus pen, a touch screen, and the like. The foregoing and other input devices are frequently connected to the processing device 1104 through an input device interface 1142 connected to the system bus 1108, but may be connected by other interfaces, such as a parallel port, an IEEE 1394 serial port, a game port, a USB port, an IR interface, and other interfaces.

A monitor 1144 or other types of display devices are also connected to the system bus 1108 through an interface, such as a video adaptor 1146. In addition to the monitor 1144, the computer generally includes other peripheral output devices (not illustrated), such as a speaker and a printer.

The computer 1102 may be operated in a networked environment by using a logical connection to one or more remote computers, such as remote computer(s) 1148, through wired and/or wireless communication. The remote computer(s) 1148 may be a work station, a computing device computer, a router, a personal computer, a portable computer, a microprocessor-based entertainment device, a peer device, and other general network nodes, and generally includes some or an entirety of the constituent elements described for the computer 1102, but only a memory storage device 1150 is illustrated for simplicity. The illustrated logical connection includes a wired/wireless connection to a local area network (LAN) 1152 and/or a larger network, for example, a wide area network (WAN) 1154. The LAN and WAN networking environments are general in an office and a company, and make an enterprise-wide computer network, such as an Intranet, easy, and all of the LAN and WAN networking environments may be connected to a worldwide computer network, for example, the Internet.

When the computer 1102 is used in the LAN networking environment, the computer 1102 is connected to the local network 1152 through a wired and/or wireless communication network interface or an adaptor 1156. The adaptor 1156 may make wired or wireless communication to the LAN 1152 easy, and the LAN 1152 also includes a wireless access point installed therein for the communication with the wireless adaptor 1156. When the computer 1102 is used in the WAN networking environment, the computer 1102 may include a modem 1158, is connected to a communication computing device on a WAN 1154, or includes other means setting communication through the WAN 1154 via the Internet. The modem 1158, which may be an embedded or outer-mounted and wired or wireless device, is connected to the system bus 1108 through a serial port interface 1142. In the networked environment, the program modules described for the computer 1102 or some of the program modules may be stored in a remote memory/storage device 1150. The illustrated network connection is illustrative, and those skilled in the art will appreciate well that other means setting a communication link between the computers may be used.

The computer 1102 performs an operation of communicating with a predetermined wireless device or entity, for example, a printer, a scanner, a desktop and/or portable computer, a portable data assistant (PDA), a communication satellite, predetermined equipment or place related to a wirelessly detectable tag, and a telephone, which is disposed by wireless communication and is operated. The operation includes a wireless fidelity (Wi-Fi) and Bluetooth wireless technology at least. Accordingly, the communication may have a pre-defined structure, such as a network in the related art, or may be simply ad hoc communication between at least two devices.

The Wi-Fi enables a connection to the Internet and the like even without a wire. The Wi-Fi is a wireless technology, such as a cellular phone, which enables the device, for example, the computer, to transmit and receive data indoors and outdoors, that is, in any place within a communication range of a base station. A Wi-Fi network uses a wireless technology, which is called IEEE 802.11 (a, b, g, etc.) for providing a safe, reliable, and high-rate wireless connection. The Wi-Fi may be used for connecting the computer to the computer, the Internet, and the wired network (IEEE 802.3 or Ethernet is used). The Wi-Fi network may be operated at, for example, a data rate of 11 Mbps (802.11a) or 54 Mbps (802.11b) in an unauthorized 2.4 and 5 GHz wireless band, or may be operated in a product including both bands (dual bands).

Those skilled in the art may appreciate that information and signals may be expressed by using predetermined various different technologies and techniques. For example, data, indications, commands, information, signals, bits, symbols, and chips referable in the foregoing description may be expressed with voltages, currents, electromagnetic waves, magnetic fields or particles, optical fields or particles, or a predetermined combination thereof.

Those skilled in the art will appreciate that the various illustrative logical blocks, modules, processors, means, circuits, and algorithm operations described in relationship to the embodiments disclosed herein may be implemented by electronic hardware (for convenience, called “software” herein), various forms of program or design code, or a combination thereof. In order to clearly describe compatibility of the hardware and the software, various illustrative components, blocks, modules, circuits, and operations are generally illustrated above in relation to the functions of the hardware and the software. Whether the function is implemented as hardware or software depends on design limits given to a specific application or an entire system. Those skilled in the art may perform the function described by various schemes for each specific application, but it shall not be construed that the determinations of the performance depart from the scope of the present disclosure.

Various embodiments presented herein may be implemented by a method, a device, or a manufactured article using a standard programming and/or engineering technology. A term “manufactured article” includes a computer program, a carrier, or a medium accessible from a predetermined computer-readable storage device. For example, the computer-readable storage medium includes a magnetic storage device (for example, a hard disk, a floppy disk, and a magnetic strip), an optical disk (for example, a CD and a DVD), a smart card, and a flash memory device (for example, an EEPROM, a card, a stick, and a key drive), but is not limited thereto. Further, various storage media presented herein include one or more devices and/or other machine-readable media for storing information.

It shall be understood that a specific order or a hierarchical structure of the operations included in the presented processes is an example of illustrative accesses. It shall be understood that a specific order or a hierarchical structure of the operations included in the processes may be rearranged within the scope of the present disclosure based on design priorities. The accompanying method claims provide various operations of elements in a sample order, but it does not mean that the claims are limited to the presented specific order or hierarchical structure.

The description of the presented embodiments is provided so as for those skilled in the art to use or carry out the present disclosure. Various modifications of the embodiments may be apparent to those skilled in the art, and general principles defined herein may be applied to other embodiments without departing from the scope of the present disclosure. Accordingly, the present disclosure is not limited to the embodiments suggested herein, and shall be interpreted within the broadest meaning range consistent to the principles and new characteristics presented herein.

What is claimed is:

1. A method for placing a semiconductor cell performed by a computing device, the method comprising:
determining a placement location of a macro cell in a design area using a reinforcement learning model;
determining a candidate direction for shifting the placement location of the macro cell determined by the reinforcement learning model; and
shifting the placement location of the macro cell based on the determined candidate direction,
wherein the determined candidate direction includes at least one direction of a direction facing a corner of the design area or a direction facing an edge of the design area.

2. The method of claim 1, wherein the design area includes a canvas for placing the semiconductor cell.

3. The method of claim 2, wherein the direction facing the corner of the design area includes:
a direction facing a corner closest to the placement location of the macro cell among a plurality of corners of the canvas.

4. The method of claim 3, wherein the direction facing the corner closest to the placement location of the macro cell is determined based on identifying a quadrant includes the macro cells among quadrants of the canvas.

5. The method of claim 2, wherein the direction facing the edge of the design area is determined based on a bounding box of a macro group includes the macro cells.

6. The method of claim 5, wherein the direction facing the edge of the design area includes at least one direction of:
a direction facing an edge of the canvas which is closest to the bounding box of the macro group; or
a direction facing an edge of the canvas which is second closest to the bounding box of the macro group.

7. The method of claim 1, wherein the determining of the candidate direction for shifting the placement location of the macro cell determined by the reinforcement learning model includes:
determining a plurality of candidate directions for shifting the placement location of the macro cell,
wherein the shifting of the placement location of the macro cell includes:
shifting the placement location of the macro cell based on a plurality of determined candidate directions.

8. The method of claim 7, wherein the plurality of determined candidate directions includes:
a direction facing one corner among a plurality of corners of the design area, and
a direction facing one edge among a plurality of edges of the design area.

9. The method of claim 7, wherein the plurality of determined candidate directions includes:
two or more directions facing two or more edges among a plurality of edges of the design area.

10. The method of claim 7, wherein the plurality of determined candidate directions includes:
a direction facing one corner among a plurality of corners of the design area, and
two or more directions facing two or more edges among a plurality of edges of the design area.

11. The method of claim 10, wherein the direction facing one corner among the plurality of corners of the design area is determined by a unit of an individual macro cell.

12. The method of claim 10, wherein the directions facing two or more edges among the plurality of edges of the design area is determined by a unit of a macro group including a plurality of macro cells.

13. The method of claim 1, wherein the placement location of the macro cell determined by the reinforcement learning model includes at least one of:
a placement location of the macro cell, or
a placement location by a unit of a macro group including the macro cells.

14. The method of claim 1, wherein the placement location of the macro cell determined by the reinforcement learning model includes:
a final placement location determined after a reinforcement learning by the reinforcement learning model.

15. The method of claim 1, wherein the placement location of the macro cell determined by the reinforcement learning model includes:
a placement location determined during a learning process of a reinforcement learning by the reinforcement learning model.

16. The method of claim 15, wherein the placement location determined during the learning process of the reinforcement learning by the reinforcement learning model includes:
a placement location associated with a reward during an episode of the reinforcement learning.

17. The method of claim 16, wherein the reward is calculated by considering the shift of the placement location of the macro cell based on the determined candidate direction.

18. A device comprising:
at least one processor; and
a memory,
wherein the at least one processor is configured to:
determine a placement location of a macro cell in a design area using a reinforcement learning model,
determine a candidate direction for shifting the placement location of the macro cell determined by the reinforcement learning model, and
shift the placement location of the macro cell based on the determined candidate direction, and
wherein the determined candidate direction includes at least one direction of a direction facing a corner of the design area or a direction facing an edge of the design area.

19. A computer program stored in a non-transitory computer-readable storage medium, the computer program causing at least one processor to perform operations of placing a semiconductor cell, the operations comprising:
an operation of determining a placement location of a macro cell in a design area using a reinforcement learning model;
an operation of determining a candidate direction for shifting the placement location of the macro cell determined by the reinforcement learning model; and
an operation of shifting the placement location of the macro cell based on the determined candidate direction, and
wherein the determined candidate direction includes at least one direction of a direction facing a corner of the design area or a direction facing an edge of the design area.
